(19) United States
(12) Patent Application Publication
(10) Pub. No.: US 2025/0081504 A1
(43) Pub. Date: Mar. 6, 2025

(54) SEMICONDUCTOR DEVICE, AND PRODUCTION METHOD FOR SEMICONDUCTOR DEVICE

(71) Applicant: SUMITOMO ELECTRIC INDUSTRIES, LTD., Osaka (JP)

(72) Inventor: Isao MAKABE, Osaka (JP)

(21) Appl. No.: 18/815,082

(22) Filed: Aug. 26, 2024

(30) Foreign Application Priority Data
Aug. 31, 2023 (JP) 2023-141126

(51) Int. Cl. H01L 29/778; H01L 29/20; H01L 29/45; H01L 29/66

(52) U.S. Cl. CPC H10D 30/4755; H10D 30/015; H10D 62/85; H10D 62/8503; H10D 64/62

(57) ABSTRACT

A production method for a semiconductor device includes: forming a first nitride semiconductor layer having nitrogen polarity at upper surface; forming a first dielectric film on the first nitride semiconductor layer; forming a first opening in the first dielectric film, part of the first nitride semiconductor layer being exposed from the first opening; forming a second nitride semiconductor layer inward of the first opening and on the first nitride semiconductor layer; forming a second opening in the first dielectric film after the formation of the second nitride semiconductor layer, part of the first nitride semiconductor layer being exposed from the second opening; forming a second dielectric film inward of the second opening and on the first nitride semiconductor layer; forming an ohmic electrode that is in an ohmic contact with the second nitride semiconductor layer; and forming a gate electrode above the second opening and on the second dielectric film.

### CROSS-REFERENCE TO RELATED APPLICATIONS

This application is based on and claims priority to Japanese Patent Application No. 2023-141126, filed on Aug. 31, 2023, the entire contents of which are incorporated herein by reference.

### TECHNICAL FIELD

The present disclosure relates to semiconductor devices, and production methods for semiconductor devices.

### BACKGROUND

High electron mobility transistors (HEMTs) having a structure in which a channel layer is formed on a barrier layer, are proposed. Also, transistors in which a hafnium silicate film having a high dielectric constant is used as a gate insulating film, are proposed. See Unexamined Japanese Patent Application Publication No. 2007-329483 and PCT Japanese Translation Patent Publication No. 2010-510680.

### SUMMARY

A production method for a semiconductor device includes: forming a first nitride semiconductor layer having nitrogen polarity at an upper surface thereof; forming a first dielectric film on the first nitride semiconductor layer; forming a first opening in the first dielectric film, a part of the first nitride semiconductor layer being exposed from the first opening; forming a second nitride semiconductor layer inward of the first opening and on the first nitride semiconductor layer; forming a second opening in the first dielectric film after the formation of the second nitride semiconductor layer, a part of the first nitride semiconductor layer being exposed from the second opening; forming a second dielectric film inward of the second opening and on the first nitride semiconductor layer; forming an ohmic electrode that is in an ohmic contact with the second nitride semiconductor layer; and forming a gate electrode above the second opening and on the second dielectric film.

### BRIEF DESCRIPTION OF THE DRAWINGS

FIG. 1 is a cross-sectional view illustrating a semiconductor device according to an embodiment of the present disclosure;

FIG. 2 is a cross-sectional view illustrating a production method for the semiconductor device according to the embodiment (part 1);

FIG. 3 is a cross-sectional view illustrating the production method for the semiconductor device according to the embodiment (part 2);

FIG. 4 is a cross-sectional view illustrating the production method for the semiconductor device according to the embodiment (part 3);

FIG. 5 is a cross-sectional view illustrating the production method for the semiconductor device according to the embodiment (part 4);

FIG. 6 is a cross-sectional view illustrating the production method for the semiconductor device according to the embodiment (part 5);

FIG. 7 is a cross-sectional view illustrating the production method for the semiconductor device according to the embodiment (part 6);

FIG. 8 is a cross-sectional view illustrating the production method for the semiconductor device according to the embodiment (part 7);

FIG. 9 is a cross-sectional view illustrating the production method for the semiconductor device according to the embodiment (part 8);

FIG. 10 is a cross-sectional view illustrating the production method for the semiconductor device according to the embodiment (part 9);

FIG. 11 is a cross-sectional view illustrating the production method for the semiconductor device according to the embodiment (part 10);

FIG. 12 is a cross-sectional view illustrating the production method for the semiconductor device according to the embodiment (part 11);

FIG. 13 is a cross-sectional view illustrating the production method for the semiconductor device according to the embodiment (part 12);

FIG. 14 is a cross-sectional view illustrating the production method for the semiconductor device according to the embodiment (part 13);

FIG. 15 is a cross-sectional view illustrating the production method for the semiconductor device according to the embodiment (part 14); and

FIG. 16 is a cross-sectional view illustrating a semiconductor device according to a modified example of the embodiment.

### DETAILED DESCRIPTION

When producing HEMTs having a structure in which a channel layer is formed on a barrier layer and that includes a hafnium silicate film as a gate insulating film, control of etching and the like are challenging.

The present disclosure provides a semiconductor device that is more readily produced, and a production method for the semiconductor device.

According to the present disclosure, semiconductor devices can be more readily produced.

### Description of Embodiments of the Present Disclosure

First, embodiments of the present disclosure will be described below.

[1] A production method for a semiconductor device according to one aspect of the present disclosure includes: forming a first nitride semiconductor layer having nitrogen polarity at an upper surface thereof; forming a first dielectric film on the first nitride semiconductor layer; forming a first opening in the first dielectric film, a part of the first nitride semiconductor layer being exposed from the first opening; forming a second nitride semiconductor layer inward of the first opening and on the first nitride semiconductor layer; forming a second opening in the first dielectric film after the formation of the second nitride semiconductor layer, a part of the first nitride semiconductor layer being exposed from the second opening; forming a second dielectric film inward of the second opening and on the first nitride semiconductor layer; forming an ohmic electrode that is in an ohmic contact with the second nitride semiconductor layer; and forming a gate electrode above the second opening and on the second dielectric film.

The second dielectric film is formed after the formation of the first opening and the second nitride semiconductor layer. Thus, it is not necessary to etch the second dielectric film for forming the first opening. In accordance with the materials of the first dielectric film and the second dielectric film, the selectivity etching ratio between the first dielectric film and the second dielectric film is small. However, even if the selectivity etching ratio is small, the first opening can be readily formed. Therefore, a semiconductor device is readily produced.

[2] In [1], the formation of the second dielectric film may include: forming a plurality of insulating films on the first nitride semiconductor layer; and performing a thermal treatment on the plurality of insulating films, thereby forming a composite insulating film. In this case, the second dielectric film is more likely to have a high dielectric constant.

[3] In [2], the plurality of insulating films may include: a first oxide film including at least one selected from the group consisting of hafnium, lanthanum, and zirconium; and a second oxide film including at least one selected from the group consisting of silicon and aluminum. In this case, the second dielectric film is more likely to have a high dielectric constant.

[4] In [2] or [3], the formation of the second dielectric film may include nitriding the composite insulating film after performing the thermal treatment. In this case, the second dielectric film is more likely to have an especially high dielectric constant.

[5] In any one of [1] to [4], the production method may further include, between the formation of the second opening and the formation of the second dielectric film, reducing the part of the first nitride semiconductor layer exposed from the second opening using thermally decomposed ammonia. In this case, even if damage occurs in the first nitride semiconductor layer upon the formation of the second opening, damaged parts can be removed, and variation in characteristics due to the damage can be suppressed.

[6] In [1], the second dielectric film may include at least one selected from the group consisting of a silicon nitride film, an aluminum oxide film, and a silicon oxynitride film. In this case, the second dielectric film is more likely to have a high dielectric constant.

[7] In any one of [1] to [6], the first

dielectric film may be formed by a thermal film forming method using a raw material including nitrogen. In this case, nitrogen atoms can be supplied to the upper surface of the first nitride semiconductor layer upon forming the first dielectric film, thereby modifying the upper surface.

[8] A semiconductor device according to another aspect of the present disclosure includes: a first nitride semiconductor layer having nitrogen polarity on an upper surface thereof; a first dielectric film on the first nitride semiconductor layer; a first opening and a second opening that are formed in the first dielectric film, a part of the first nitride semiconductor layer being exposed from the first opening and the second opening; a second nitride semiconductor layer that is inward of the first opening and on the first nitride semiconductor layer; a second dielectric film that is inward of the second opening and on the first nitride semiconductor layer; an ohmic electrode that is in an ohmic contact with the second nitride semiconductor layer; and a gate electrode that is above the second opening and on the second dielectric film.

The second dielectric film can be formed after the formation of the first opening and the second nitride semiconductor layer, in order to produce this structure. Therefore, as described above, the semiconductor device is readily produced.

[9] In [8], a specific resistance of the second dielectric film may be higher than that of the first dielectric film. In this case, gate leakage can be suppressed by the second dielectric film, while suppressing current collapse by the first dielectric film.

In [8] or [9], a dielectric constant of the second dielectric film may be higher than that of the first dielectric film. In this case, gate leakage can be suppressed by the second dielectric film, while suppressing current collapse by the first dielectric film.

A production method for a semiconductor device according to still another aspect of the present disclosure includes: forming a first nitride semiconductor layer having nitrogen polarity at an upper surface thereof; forming a first dielectric film on the first nitride semiconductor layer; forming a gate opening in the first dielectric film, a part of the first nitride semiconductor layer being exposed from the second opening; reducing the part of the first nitride semiconductor layer exposed from the gate opening using thermally decomposed ammonia; and forming a second dielectric film inward of the gate opening and on the first nitride semiconductor layer.

### Details of Embodiments of the Present Disclosure

Embodiments of the present disclosure will be described below in detail, but the present disclosure is not limited thereto. In the present specification and drawings, components having substantially the same functional configuration are denoted by the same reference numerals, and duplicate description thereof may be omitted. In the present disclosure, “plan view” refers to viewing a target object from above.

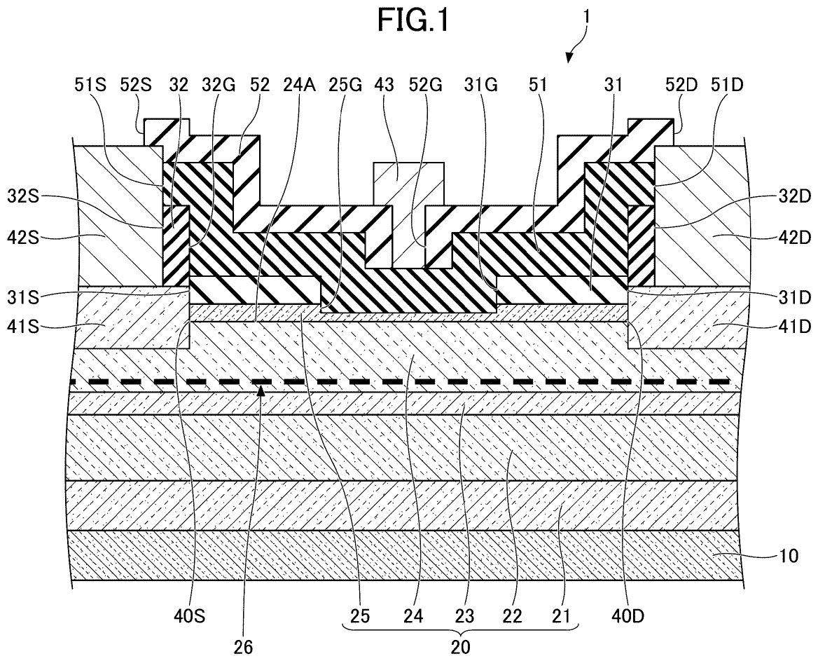

The embodiments relate to a semiconductor device including a GaN-based high electron mobility transistor (HEMT). FIG. 1 is a cross-sectional view illustrating the semiconductor device according to the embodiment.

As illustrated in FIG. 1, a semiconductor device 1 according to the embodiment mainly includes a substrate for growth 10 (hereinafter referred to as a “growth substrate 10”), a nitride semiconductor layer 20, a first dielectric film 31, an insulating film 32, a second dielectric film 51, a passivation film 52, a regrown layer 41S, a regrown layer 41D, a gate electrode 43, a source electrode 42S, and a drain electrode 42D.

The growth substrate 10 is, for example, a semi-insulating silicon carbide (SiC) substrate. When the growth substrate 10 is an SiC substrate, the upper surface of the growth substrate 10 is a surface having carbon (C) polarity (hereinafter referred to as a “C-polarity surface”). When the upper surface of the growth substrate 10 is a C-polarity surface, crystal growth of the nitride semiconductor layer 20 can be performed with the growth surface being a surface having nitrogen (N) polarity (hereinafter referred to as an “N-polarity surface”).

The nitride semiconductor layer 20 includes a buffer layer 21, a barrier layer 22, a spacer layer 23, a channel layer 24, and a cap layer 25. The nitride semiconductor layer 20 may include a nucleation layer between the growth substrate 10 and the buffer layer 21. The nitride semiconductor layer 20 is an example of the first nitride semiconductor layer.

The buffer layer 21 is on the growth substrate 10. The buffer layer 21 is, for example, an aluminum nitride (AlN) layer. The thickness of the AIN layer is, for example, 1 nanometer (nm) or greater and 2,000nanometers (nm) or smaller. The buffer layer 21 may include: an AlN layer; and a GaN layer on the AlN layer or an aluminum gallium nitride (AlGaN) layer on the AlN layer.

The barrier layer 22 is on the buffer layer 21. The barrier layer 22 is, for example, an AlGaN layer. The band gap of the barrier layer 22 is greater than the band gap of the channel layer 24. The thickness of the barrier layer 22 is, for example, 1 nm or greater and 50nm or smaller. The composition of the barrier layer 22 is, for example, Al_{Y}Ga_{1-Y}N (Y is 0.15 or more and 0.55 or less). The conductive type of the barrier layer 22 is, for example, an n-type or an undoped type (i-type). Instead of the AlGaN layer, a scandium aluminum nitride (ScAlN) layer, an indium aluminum nitride (InAlN) layer, or an indium aluminum gallium nitride (InAlGaN) layer may be used.

The spacer layer 23 is on the barrier layer 22. The spacer layer 23 is, for example, an AlN layer. The thickness of the spacer layer 23 is, for example, 0.2 nm or greater and 5 nm or smaller.

The channel layer 24 is on the spacer layer 23. The channel layer 24 is, for example, a GaN layer. The band gap of the channel layer 24 is smaller than the band gap of the barrier layer 22. The thickness of the channel layer 24 is, for example, 1 nm or greater and 50nm or smaller. Distortion occurs between: the channel layer 24; and the barrier layer 22 and the spacer layer 23 due to the difference in lattice constants thereof. This distortion induces piezoelectric charges at the interface therebetween. This generates two-dimensional electron gas (2DEG) in the channel layer 24 and near the surface of the channel layer 24 facing the barrier layer 22, thereby forming a channel region 26. The conductive type of the channel layer 24 is, for example, an n-type or an undoped type (i-type).

The cap layer 25 is on the channel layer 24. The cap layer 25 is, for example, an AlGaN layer. The thickness of the cap layer 25 is, for example, 0.2 nm or greater and 10 nm or smaller.

On the C-polarity surface of the SiC substrate, crystal growth of the buffer layer 21, the barrier layer 22, the spacer layer 23, the channel layer 24, and the cap layer 25 is performed with the growth surface being the N-polarity surface. Accordingly, the upper surface of each of the buffer layer 21, the barrier layer 22, the spacer layer 23, the channel layer 24, and the cap layer 25 has N polarity, and the lower surface of each thereof has gallium (Ga) polarity.

A source recess 40S and a drain recess 40D are formed in the nitride semiconductor layer 20. The bottom of the recess 40S and the bottom of the recess 40D are closer to the lower surface of the nitride semiconductor layer 20 than is an upper surface 24A of the channel layer 24. That is, the recess 40S and the recess 40D are formed deeper than the upper surface 24A of the channel layer 24. The bottom of the recess 40S and the bottom of the recess 40D may be in the channel layer 24, may be in the spacer layer 23, or may be in the barrier layer 22.

A recess 25G is formed in the cap layer 25. In a plan view, the recess 25G is between the recess 40S and the recess 40D. The thickness of a part of the cap layer 25 remaining at the bottom of the recess 25G is, for example, 1 nm or greater and 5 nm or smaller. That is, the distance between the lower surface of the cap layer 25 and the bottom surface of the recess 25G is, for example, 1 nm or greater and 5 nm or smaller. For example, when the thickness of the cap layer 25 is 5 nm or smaller, the recess 25G need not necessarily be formed.

The first dielectric film 31 is on the nitride semiconductor layer 20. The first dielectric film 31 is in contact with the upper surface of the cap layer 25. For example, the dielectric constant of the first dielectric film 31 is higher than that of silicon dioxide (SiO₂). The first dielectric film 31 may be a high-dielectric-constant film. The first dielectric film 31 is, for example, a silicon nitride (SiN) film. The thickness of the first dielectric film 31 is, for example, 2 nm or greater and 100 nm or smaller. A source opening 31S, a drain opening 31D, and a gate opening 31G are formed in the first dielectric film 31. The opening 31S is connected to the recess 40S, the opening 31D is connected to the recess 40D, and the opening 31G is connected to the recess 25G. The opening 31S and the opening 31D are an example of the first opening. The first opening may be called drain-source opening. The opening 31G is an example of the second opening. The second opening may be called gate opening.

The regrown layer 41S is on the channel layer 24, the spacer layer 23, or the barrier layer 22, in the recess 40S. The regrown layer 41D is on the channel layer 24, the spacer layer 23, or the barrier layer 22, in the recess 40D. The regrown layer 41S and the regrown layer 41D are, for example, an n-type GaN layer. The regrown layer 41S and the regrown layer 41D include germanium (Ge) or Si as an n-type dopant. The electrical resistance of the regrown layer 41S and the regrown layer 41D is lower than that of the channel layer 24. For example, the regrown layer 41S and the regrown layer 41D are formed through regrowth of the n-type GaN layer after the formation of the recesses 40S and 40D in the nitride semiconductor layer 20. The regrown layer 41S and the regrown layer 41D are an example of the second nitride semiconductor layer.

The insulating film 32 is on the regrown layer 41S and the regrown layer 41D. The insulating film 32 is, for example, an SiN film. A source opening 32S, a drain opening 32D, and an opening 32G are formed in the insulating film 32. A part of the regrown layer 41S is exposed from the opening 32S, a part of the regrown layer 41D is exposed from the opening 32D, and the first dielectric film 31 is exposed from the opening 32G. It is not necessary that the entirety of the first dielectric film 31 is exposed from the opening 32G. A part of the insulating film 32 may be on the first dielectric film 31.

The second dielectric film 51 is on the cap layer 25, the first dielectric film 31, and the insulating film 32. The second dielectric film 51 is inward of the opening 31G and on the cap layer 25. For example, the dielectric constant of the second dielectric film 51 is higher than that of SiO₂. The second dielectric film 51 may be a high-dielectric-constant film. The second dielectric film 51 is, for example, a dielectric oxide film or a dielectric oxynitride film. The dielectric oxide film or the dielectric oxynitride film may include at least one selected from the group consisting of hafnium (Hf), lanthanum (La), and zirconium (Zr). Also, the dielectric oxide film or the dielectric oxynitride film may include at least one selected from the group consisting of silicon (Si) and aluminum (Al). For example, the second dielectric film 51 may be a hafnium silicate (HfSiOx) film or a hafnium aluminate (HfAlOx) film. The second dielectric film 51 may be a dielectric film having insulating properties, other than the dielectric oxide film and the dielectric oxynitride film. The thickness of the second dielectric film 51 is, for example, 1 nm or greater and 30 nm or smaller. A source opening 51S and a drain opening 51D are formed in the second dielectric film 51. The opening 51S is connected to the opening 32S, and the opening 51D is connected to the opening 32D.

The source electrode 42S is on the regrown layer 41S in the openings 32S and 51S, and the drain electrode 42D is on the regrown layer 41D in the openings 32D and 51D. The source electrode 42S is in contact with the regrown layer 41S, and the drain electrode 42D is in contact with the regrown layer 41D. The source electrode 42S is in an ohmic contact with the regrown layer 41S, and the drain electrode 42D is in an ohmic contact with the regrown layer 41D. The source electrode 42S and the drain electrode 42D are an example of the ohmic electrode.

The passivation film 52 covers the second dielectric film 51, the source electrode 42S, and the drain electrode 42D. The thickness of the passivation film 52 is, for example, 5 nm or greater and 100 nm or smaller in a uniform-thickness part thereof on the second dielectric film 51. A source opening 52S, a drain opening 52D, and a gate opening 52G are formed in the passivation film 52. A part of the source electrode 42S is exposed from the opening 52S, and a part of the drain electrode 42D is exposed from the opening 52D. The opening 52G is inward of the opening 31G in a plan view.

In a plan view, the gate electrode 43 is between the source electrode 42S and the drain electrode 42D. The gate electrode 43 is on the passivation film 52 and the second dielectric film 51, and is in contact with the second dielectric film 51 through the opening 52G.

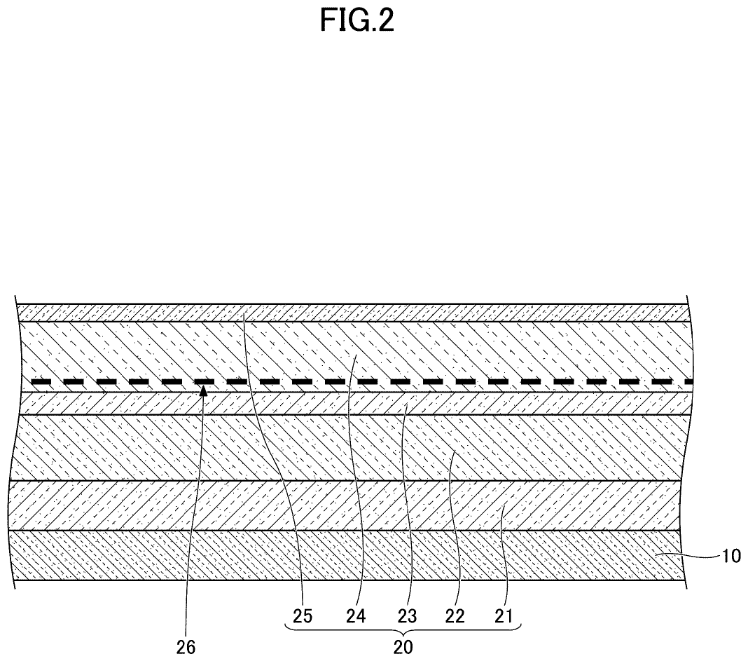

Next, a production method for the semiconductor device 1 according to the embodiment will be described. FIGS. 2 to 15 are cross-sectional views illustrating the production method for the semiconductor device 1 according to the embodiment.

First, as illustrated in FIG. 2, a nitride semiconductor layer 20 is formed on the growth substrate 10, for example, through metal organic chemical vapor deposition (MOCVD). In the formation of the nitride semiconductor layer 20, the buffer layer 21, the barrier layer 22, the spacer layer 23, the channel layer 24, and the cap layer 25 are formed sequentially.

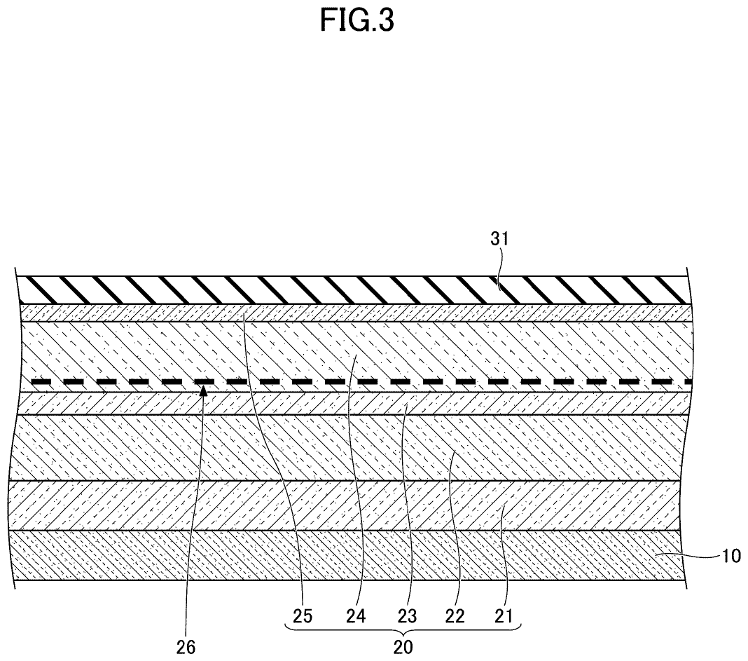

Next, as illustrated in FIG. 3, the first dielectric film 31 is formed on the nitride semiconductor layer 20. The first dielectric film 31 is formed, for example, through thermal deposition, such as thermal CVD using a low pressure chemical vapor deposition (LPCVD) apparatus. When the SiN film is formed as the first dielectric film 31, silane (SiH₄), ammonia (NH₃), and the like are used as raw materials.

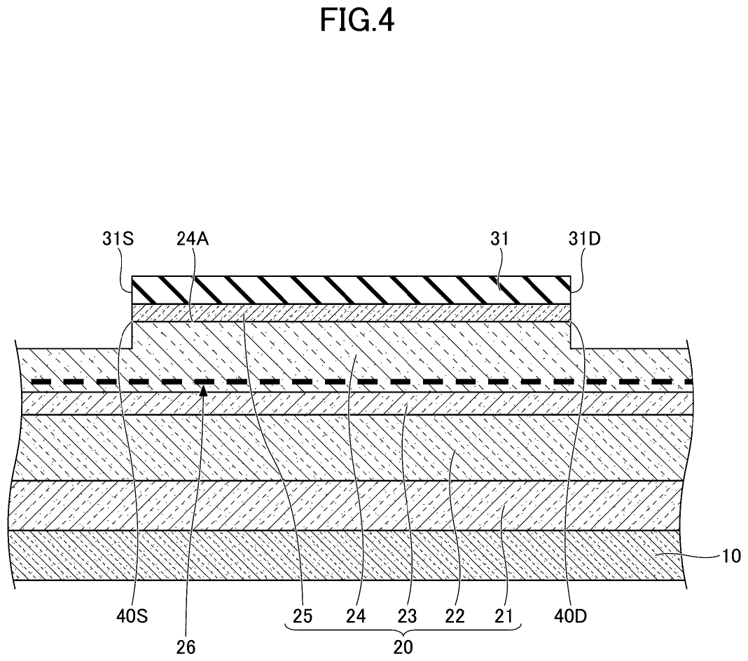

Next, as illustrated in FIG. 4, the source opening 31S and the drain opening 31D are formed in the first dielectric film 31, and the source recess 40S and the drain recess 40D are formed in the nitride semiconductor layer 20. The bottom of the recess 40S and the bottom of the recess 40D may be closer to the lower surface of the nitride semiconductor layer 20 than is the upper surface 24A of the channel layer 24. That is, the recess 40S and the recess 40D may be formed deeper than the upper surface 24A of the channel layer 24. The bottom of the recess 40S and the bottom of the recess 40D may be in the channel layer 24, may be in the spacer layer 23, or may be in the barrier layer 22.

The openings 31S and 31D and the recesses 40S and 40D can be formed, for example, through reactive ion etching (RIE) using an unillustrated mask. For example, a fluorine (F)-based gas is used as the reactive gas in the formation of the openings 31S and 31D, and a chlorine (Cl)-based gas is used as the reactive gas in the formation of the recesses 40S and 40D. The RIE using an F-based gas provides a high selectivity etching ratio between the first dielectric film 31 and the nitride semiconductor layer 20. Thus, etching residues are unlikely to occur during the formation of the openings 31S and 31D.

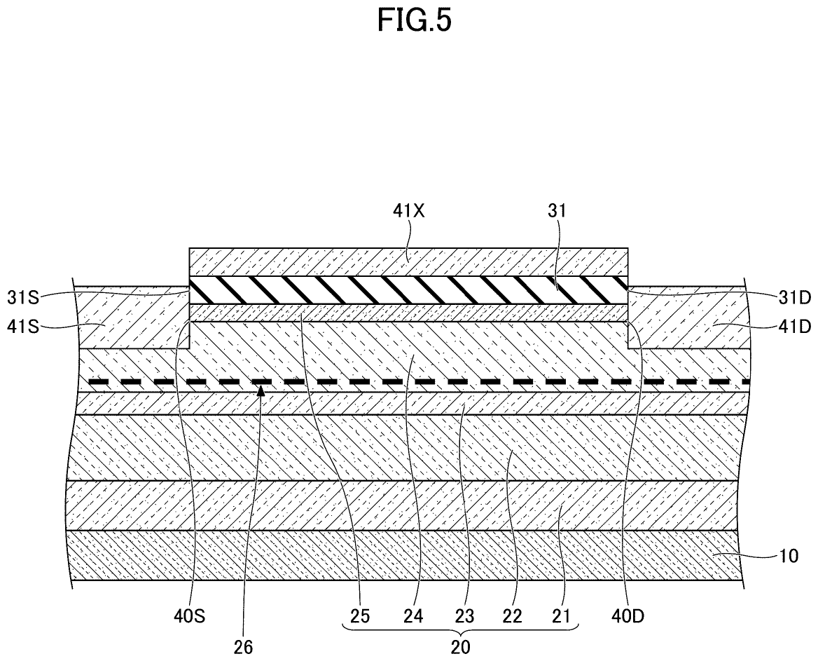

Next, as illustrated in FIG. 5, the regrown layer 41S is formed on the channel layer 24, over the spacer layer 23, and over the barrier layer 22 in the recess 40S, and the regrown layer 41D is formed on the channel layer 24, over the spacer layer 23, and over the barrier layer 22 in the recess 40D. The regrown layer 41S and the regrown layer 41D can be formed, for example, through physical vapor deposition (PVD), such as vapor deposition, sputtering, or the molecular beam epitaxy (MBE) method. Upon forming the regrown layer 41S and the regrown layer 41D, a layer 41X is formed on the first dielectric film 31, the layer 41X being formed of a material the same as that of the regrown layer 41S and the regrown layer 41D. Unlike the regrown layer 41S and the regrown layer 41D, the layer 41X does not epitaxially grow on the first dielectric film 31.

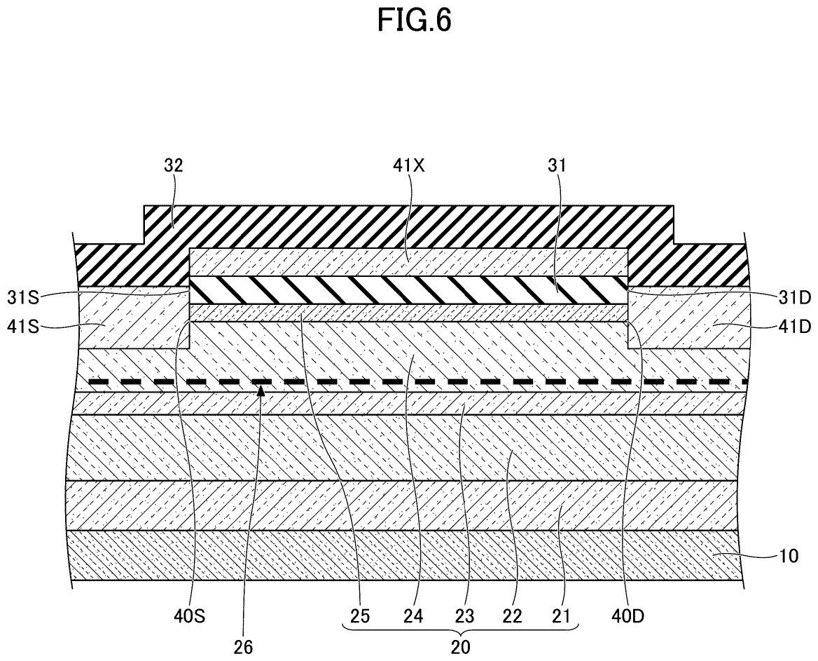

Next, as illustrated in FIG. 6, an insulating film 32 is formed on the regrown layer 41S, the regrown layer 41D, and the layer 41X. The insulating film 32 is formed, for example, through plasma CVD.

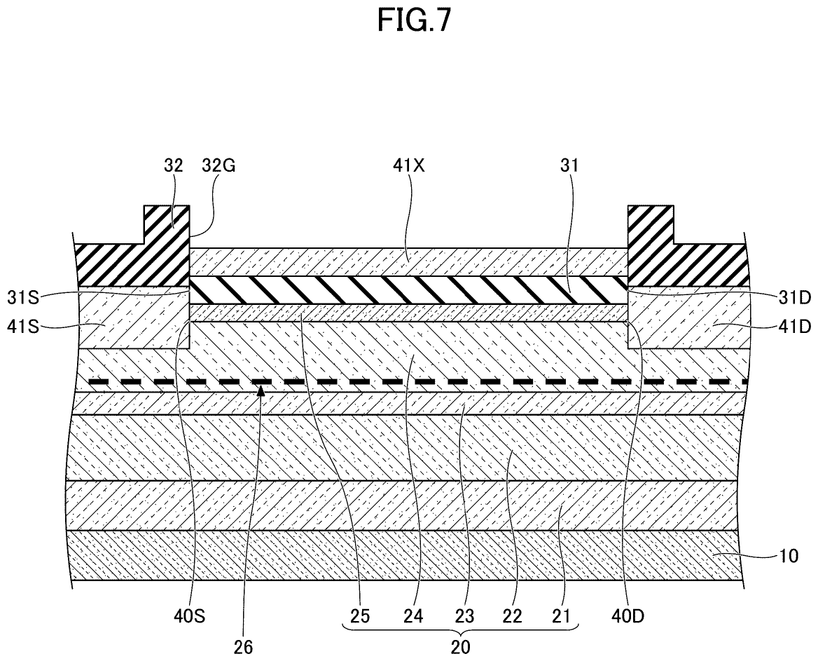

Next, as illustrated in FIG. 7, the opening 32G is formed in the insulating film 32. The opening 32G can be formed, for example, through RIE using an unillustrated mask. For example, in the formation of the opening 32G, an F-based gas is used as the reactive gas.

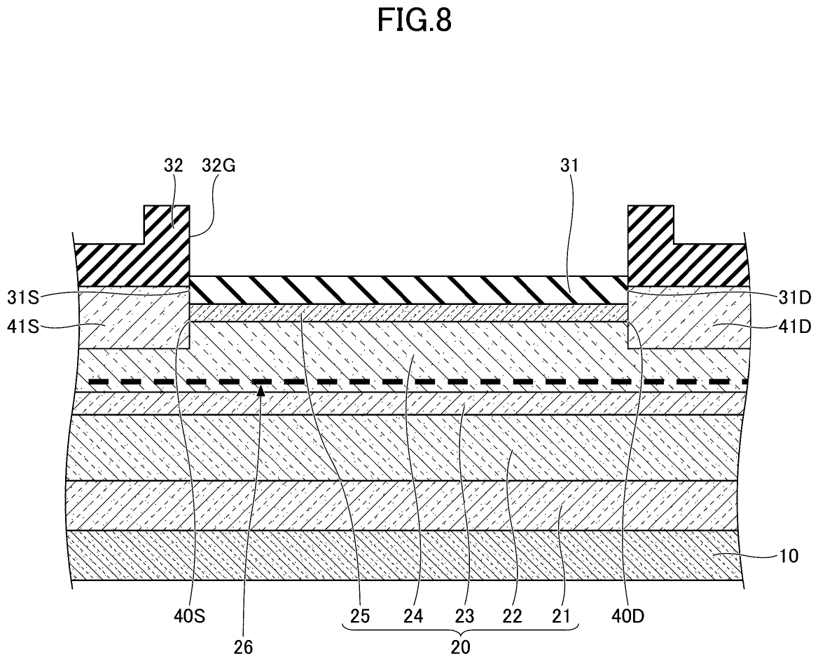

Next, as illustrated in FIG. 8, the layer 41X is removed. The layer 41X can be removed, for example, using tetramethylammonium hydroxide (TMAH). For the removal of the layer 41X, an alkaline solution, such as sodium hydroxide (NaOH), ammonium chloride (NH₄Cl), or the like, may be used.

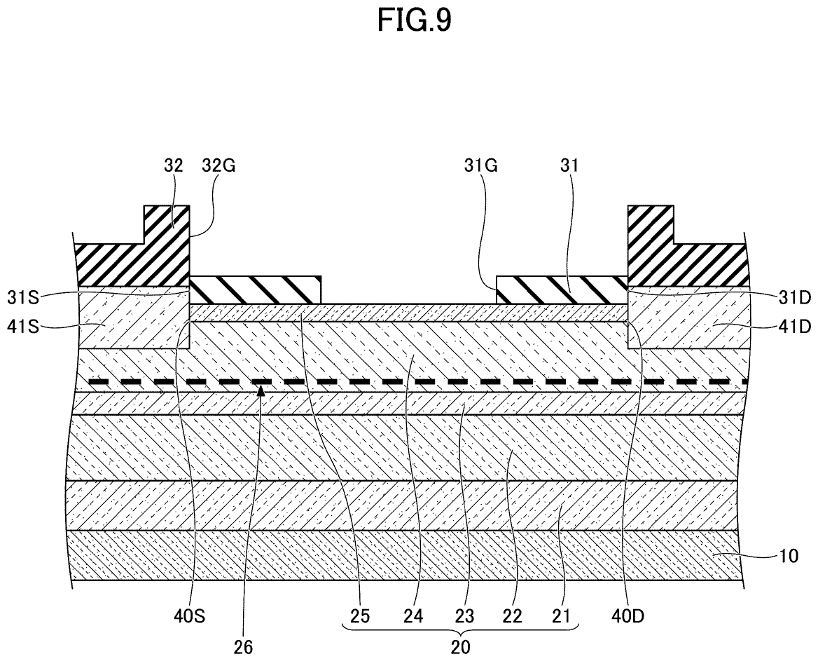

Next, as illustrated in FIG. 9, the opening 31G is formed in the first dielectric film 31. The opening 31G can be formed, for example, through RIE using an unillustrated mask. For example, in the formation of the opening 31G, an F-based gas is used as the reactive gas.

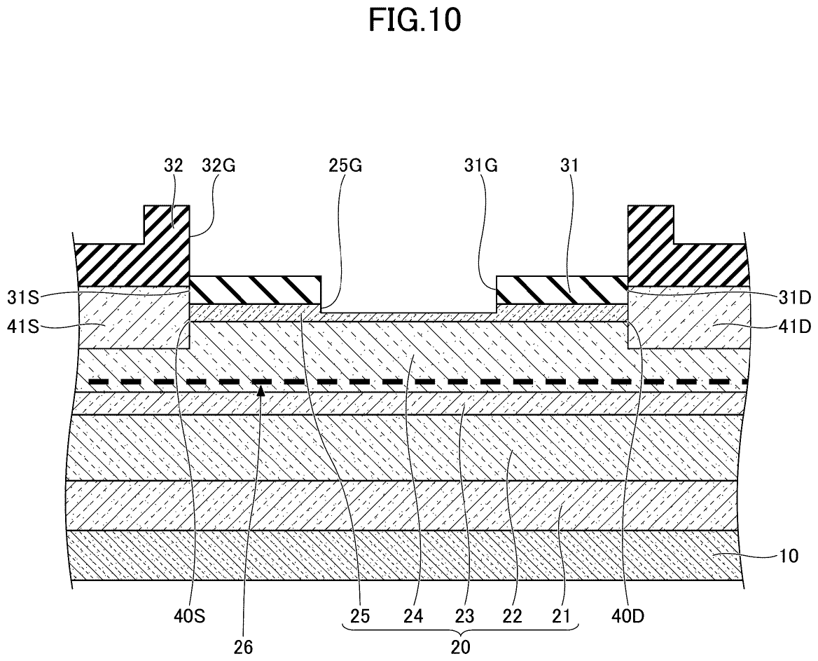

Next, the part of the cap layer 25 exposed from the opening 31G is reduced using thermally decomposed NH₃. For example, temperature of the chamber may be set in a range of 700 degree Celsius (C) or higher and 900° C. or lower for thermally decomposing NH₃. As a result, as illustrated in FIG. 10, the surface layer of the cap layer 25 exposed from the opening 31G is removed, and the recess 25G is formed. Even if the surface layer of the cap layer 25 is damaged during the formation of the opening 31G, the damaged part is removed through this reduction treatment. For example, a new surface of the cap layer 25 after removing the damaged part has an arithmetic average roughness Ra within a range from 0.4 nm to 1 nm.

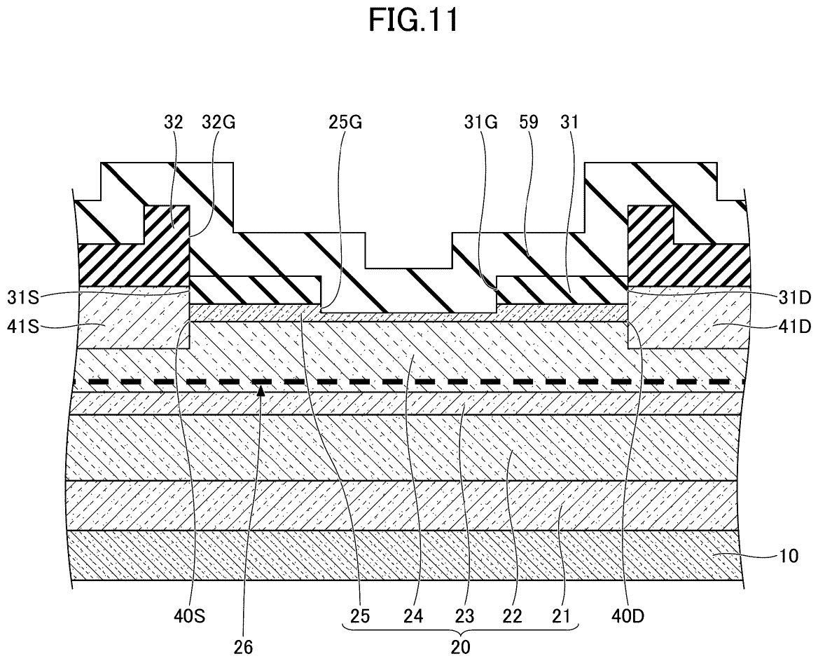

Next, as illustrated in FIG. 11, a stacked film 59 including a plurality of insulating films is formed. For example, the insulating films include: a first oxide film including at least one selected from the group consisting of hafnium, lanthanum, and zirconium; and a second oxide film including at least one selected from the group consisting of silicon and aluminum. The stacked film 59 may be a multilayered film in which the first oxide film and the second oxide film are stacked alternately. The first oxide film and the second oxide film are formed, for example, through atomic layer deposition (ALD).

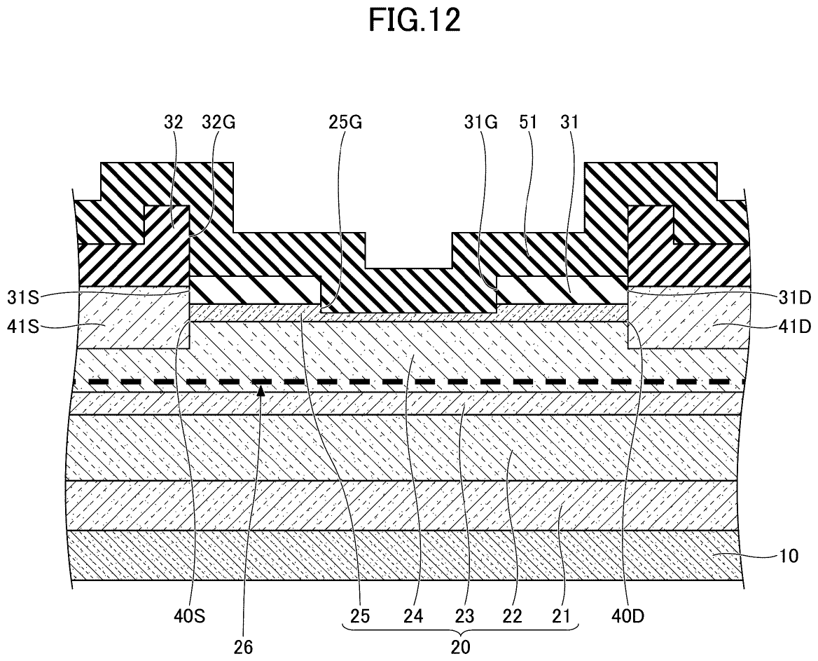

Next, as illustrated in FIG. 12, the stacked film 59 including the insulating films is subjected to a thermal treatment, thereby forming a composite insulating film as the second dielectric film 51. When the first insulating film is a hafnium oxide (HfOx) film and the second insulating film is a silicon oxide (SiOx) film, an HfSiOx film is formed as the second dielectric film 51. The temperature of the thermal treatment is, for example, about 700° C.

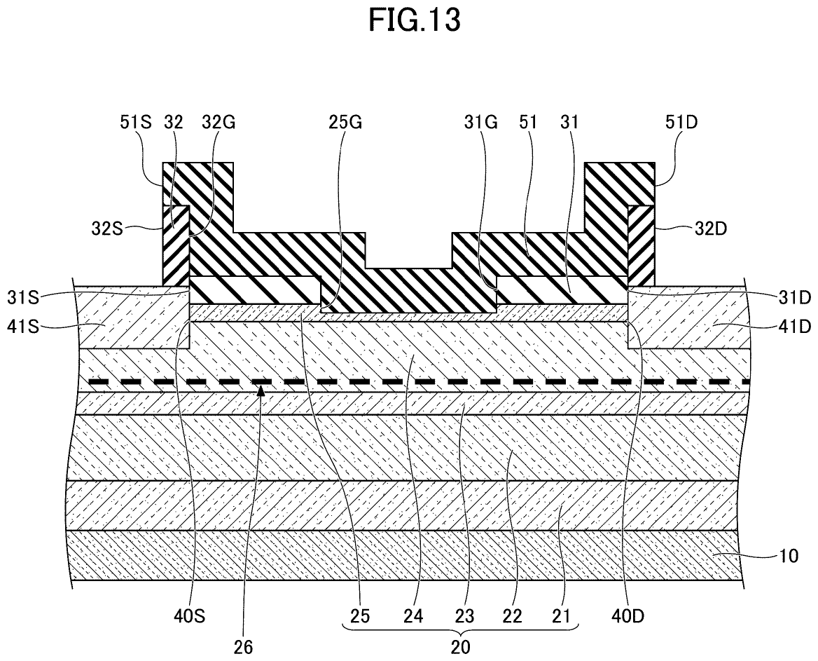

Next, as illustrated in FIG. 13, the source opening 51S and the drain opening 51D are formed in the second dielectric film 51, and the source opening 32S and the drain opening 32D are formed in the insulating film 32. The openings 51S, 51D, 32S, and 32D can be formed, for example, through RIE using an unillustrated mask. For example, in the formation of the openings 51S and 51D, a Cl-based gas is used as the reactive gas. In the formation of the openings 32S and 32D, an F-based gas is used as the reactive gas. The RIE using a Cl-based gas provides a high selectivity etching ratio between the second dielectric film 51 and the insulating film 32. Thus, etching residues are unlikely to occur during the formation of the openings 51S and 51D. The RIE using an F-based gas provides a high selectivity etching ratio between the insulating film 32 and the regrown layers 41S and 41D. Thus, etching residues are unlikely to occur during the formation of the openings 32S and 32D. The insulating film 32 functions as an etching stopper during the formation of the openings 51S and 51D.

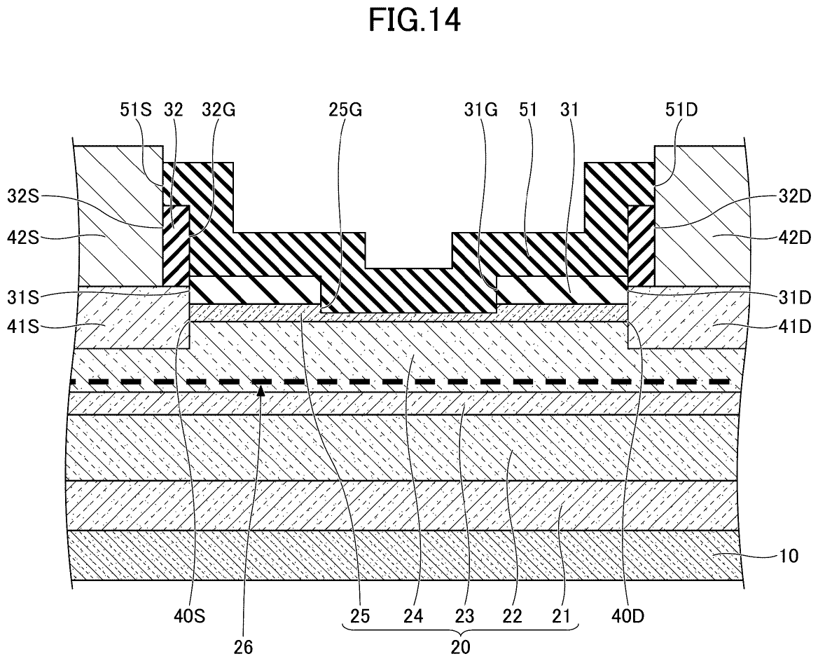

Next, as illustrated in FIG. 14, the source electrode 42S is formed on the regrown layer 41S in the openings 32S and 51S, and the drain electrode 42D is formed on the regrown layer 41D in the openings 32D and 51D. In the formation of the source electrode 42S and the drain electrode 42D, first, an unillustrated metal layer of the source electrode 42S and the drain electrode 42D is formed. Upon forming the metal layer, for example, film formation is performed using an unillustrated growth mask having an opening formed in a region in which the metal layer is to be formed. Subsequently, the growth mask is removed together with the unillustrated metal layer formed thereon. That is, lift-off is performed.

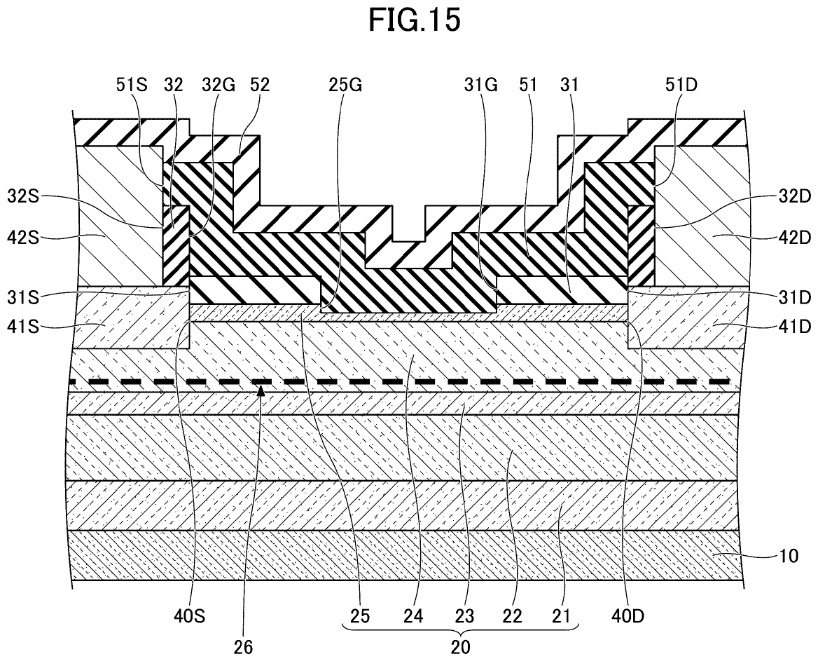

Next, as illustrated in FIG. 15, a passivation film 52 is formed on the second dielectric film 51, the source electrode 42S, and the drain electrode 42D. The passivation film 52 covers the second dielectric film 51, the source electrode 42S, and the drain electrode 42D.

Next, the gate opening 52G is formed in the passivation film 52 (see FIG. 1). The opening 52G can be formed, for example, through RIE using an unillustrated mask.

Next, the gate electrode 43 in contact with the second dielectric film 51 through the opening 52G is formed on the passivation film 52 and the second dielectric film 51 (see FIG. 1). Upon forming the gate electrode 43, for example, film formation of a metal layer is performed using an unillustrated growth mask having an opening formed in a region in which the gate electrode 43 is to be formed. Subsequently, the growth mask is removed together with the unillustrated metal layer formed thereon. That is, lift-off is performed.

Next, the source opening 52S and the drain opening 52D are formed in the passivation film 52 (see FIG. 1). The openings 52S and 52D can be formed, for example, through RIE using an unillustrated mask.

In this manner, the semiconductor device 1 can be produced.

According to the semiconductor device 1 according to the embodiment, the upper surfaces of the barrier layer 22 and the channel layer 24 have N polarity, and thus the distance between: the channel region 26; and the source electrode 42S and the drain electrode 42D can be readily reduced, and the resistance can be readily reduced.

Also, the second dielectric film 51 functioning as a gate insulating film is formed after the formation of the openings 31S and 31D for forming the regrown layers 41S and 41D. Thus, the second dielectric film 51 need not to be etched for forming the openings 31S and 31D. In accordance with the materials of the first dielectric film 31 and the second dielectric film 51, the selectivity etching ratio between the first dielectric film 31 and the second dielectric film 51 is small. However, even if the selectivity etching ratio is small, the openings 31S and 31D can be readily formed with high accuracy. Thus, an increase in the contact resistance due to etching residues can be readily suppressed. Therefore, according to the present embodiment, the semiconductor device 1 is readily produced.

Etching residues are not appreciably generated during the formation of the recesses 40S and 40D, during the formation of the openings 51S and 51D, and during the formation of the openings 32S and 32D. Therefore, etching is readily controlled in these steps.

When forming the second dielectric film 51, by forming a composite insulating film, such as an HfSiOx film or the like, the gate insulating film is likely to have a high dielectric constant. When the stacked film 59 includes: the first oxide film including at least one selected from the group consisting of Hf, La, and Zr; and the second oxide film including at least one selected from the group consisting of Si and Al, the gate insulating film is likely to have a high dielectric constant.

Further, when the part of the cap layer 25 exposed from the opening 31G is reduced using the thermally decomposed NH₃, i.e., the recess 25G is formed, after the formation of the opening 31G, the damaged part of the cap layer 25 can be removed. The damaged part itself may cause variation in the characteristics of the semiconductor device 1. In addition, during the thermal treatment for forming the composite insulating film, atoms may be diffused from the damaged part to the stacked film 59, and the cap layer 25 may become excessively thin or an opening may be formed in the cap layer 25. In these cases, the threshold may be varied, pinch-off characteristics may be degraded, and gate leakage may be increased. Meanwhile, by removing the damaged part through the reduction treatment, diffusion of atoms forming the cap layer 25 can be readily suppressed. In addition, modification of the surface of the cap layer 25 by N atoms included in NH₃ is also performed. The reduction of the part exposed from the opening 31G of the cap layer 25 need not necessarily be performed.

By forming the first dielectric film 31 through thermal deposition using a raw material including nitrogen, N atoms can be supplied to the upper surface of the cap layer 25 during the formation of the first dielectric film 31, thereby modifying the upper surface of the cap layer 25.

The cap layer 25 is not limited to the AlGaN layer, and may be an aluminum nitride (AlN) layer. When the cap layer 25 is an AlN layer, the cap layer 25 is unlikely to be damaged. Also, the recess 25G formed through the reduction treatment is likely to be shallow. When the cap layer 25 is an AlN layer, the thickness of the cap layer 25 may be 0.2 nm or greater and smaller than 2.0 nm.

The second dielectric film 51 need not to include a composite insulating film including at least one selected from the group consisting of hafnium, lanthanum, and zirconium. The second dielectric film 51 may include at least one selected from the group consisting of SiN films, aluminum oxide (Al₂O₃) films, and silicon oxynitride (SiON) films. When the second dielectric film 51 includes at least one selected from the group consisting of SiN films, Al₂O₃ films, and SiON films, the second dielectric film 51 can have a high dielectric constant. The second dielectric film 51 may be formed in the same chamber as that used for reducing the part of the cap layer 25 exposed from the opening 31G without exposure to the atmosphere. Alternatively, the second dielectric film 51 may be formed in a chamber different from the chamber used for reducing the part of the cap layer 25 exposed from the opening 31G. For example, the SiN film and the SiON film can be formed through plasma CVD, and the Al₂O₃ film can be formed through ALD. When the second dielectric film 51 includes no composite insulating film, the formation and the thermal treatment of the stacked film 59 are not necessary. The second dielectric film 51 can be formed instead of the stacked film 59.

Even if both the first dielectric film 31 and the second dielectric film 51 are an SiN film, the quality of the film is different between the first dielectric film 31 formed through thermal deposition and the second dielectric film 51 formed through plasma CVD. For example, the concentration of hydrogen (H) atoms in the first dielectric film 31 may be higher than that of H atoms in the second dielectric film 51, and the specific resistance of the second dielectric film 51 may be higher than that of the first dielectric film 31. When the specific resistance of the second dielectric film 51 is higher than the specific resistance of the first dielectric film 31, gate leakage can be suppressed by the second dielectric film 51 while suppressing electron trap by the first dielectric film 31 to suppress current collapse.

Regardless of the material, the specific resistance of the second dielectric film 51 may be higher than the specific resistance of the first dielectric film 31, and the dielectric constant of the second dielectric film 51 may be higher than the dielectric constant of the first dielectric film 31. In any case, gate leakage can be suppressed by the second dielectric film 51 while suppressing current collapse by the first dielectric film 31.

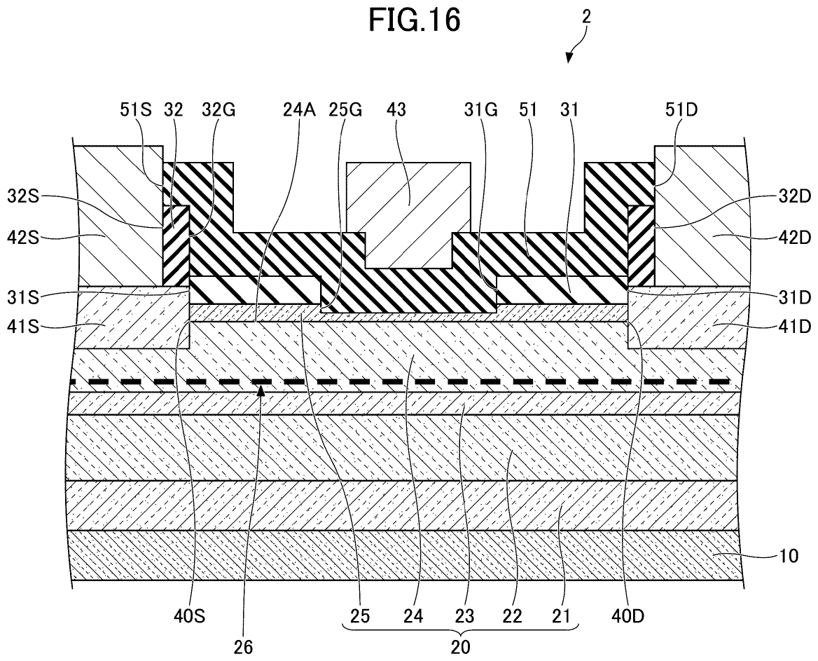

Next, a modified example of the embodiment will be described. FIG. 16 is a cross-sectional view illustrating a semiconductor device according to a modified example of the embodiment.

A semiconductor device 2 according to the modified example does not include the passivation film 52, and the gate electrode 43 is formed on the second dielectric film 51. The other configurations of the semiconductor device 2 are the same as those of the semiconductor device 1. The same effects as those of the semiconductor device 1 can be obtained by the semiconductor device 2.

Although the embodiments have been described above in detail, the present disclosure is not limited to the specific embodiments. Various modifications and changes are possible within the scope of the claims recited.

What is claimed is:

1. A production method for a semiconductor device, the production method comprising:
forming a first nitride semiconductor layer having nitrogen polarity at an upper surface thereof;
forming a first dielectric film on the first nitride semiconductor layer;
forming a first opening in the first dielectric film, a part of the first nitride semiconductor layer being exposed from the first opening;
forming a second nitride semiconductor layer inward of the first opening and on the first nitride semiconductor layer;
forming a second opening in the first dielectric film after the formation of the second nitride semiconductor layer, a part of the first nitride semiconductor layer being exposed from the second opening;
forming a second dielectric film inward of the second opening and on the first nitride semiconductor layer;
forming an ohmic electrode that is in an ohmic contact with the second nitride semiconductor layer; and
forming a gate electrode above the second opening and on the second dielectric film.

2. The production method for the semiconductor device according to claim 1, wherein
the formation of the second dielectric film includes:
forming a plurality of insulating films on the first nitride semiconductor layer; and
performing a thermal treatment on the plurality of insulating films, thereby forming a composite insulating film.

3. The production method for the semiconductor device according to claim 2, wherein
the plurality of insulating films include:
a first oxide film including at least one selected from the group consisting of hafnium, lanthanum, and zirconium; and
a second oxide film including at least one selected from the group consisting of silicon and aluminum.

4. The production method for the semiconductor device according to claim 2, wherein
the formation of the second dielectric film includes
nitriding the composite insulating film after performing the thermal treatment.

5. The production method for the semiconductor device according to claim 1, further comprising:
between the formation of the second opening and the formation of the second dielectric film, reducing the part of the first nitride semiconductor layer exposed from the second opening using thermally decomposed ammonia.

6. The production method for the semiconductor device according to claim 1, wherein
the second dielectric film includes at least one selected from the group consisting of a silicon nitride film, an aluminum oxide film, and a silicon oxynitride film.

7. The production method for the semiconductor device according to claim 1, wherein
the first dielectric film is formed by a thermal film forming method using a raw material including nitrogen.

8. A semiconductor device, comprising:
a first nitride semiconductor layer having nitrogen polarity on an upper surface thereof;
a first dielectric film on the first nitride semiconductor layer;
a first opening and a second opening that are formed in the first dielectric film, a part of the first nitride semiconductor layer being exposed from the first opening and the second opening;
a second nitride semiconductor layer that is inward of the first opening and on the first nitride semiconductor layer;
a second dielectric film that is inward of the second opening and on the first nitride semiconductor layer;
an ohmic electrode that is in an ohmic contact with the second nitride semiconductor layer; and
a gate electrode that is above the second opening and on the second dielectric film.

9. The semiconductor device according to claim 8, wherein
a specific resistance of the second dielectric film is higher than that of the first dielectric film.

10. The semiconductor device according to claim 8, wherein
a dielectric constant of the second dielectric film is higher than that of the first dielectric film.

11. A production method for a semiconductor device, the production method comprising:
forming a first nitride semiconductor layer having nitrogen polarity at an upper surface thereof;
forming a first dielectric film on the first nitride semiconductor layer;
forming a gate opening in the first dielectric film, a part of the first nitride semiconductor layer being exposed from the second opening;
reducing the part of the first nitride semiconductor layer exposed from the gate opening using thermally decomposed ammonia; and
forming a second dielectric film inward of the gate opening and on the first nitride semiconductor layer.
